(19) United States
(12) Patent Application Publication
(10) Pub. No.: US 2026/0312270 A1
(43) Pub. Date: Oct. 8, 2026

(54) SIGNAL TRANSMISSION STRUCTURE FOR SIGNAL TRANSMISSION IN MULTI-LAYER CIRCUIT BOARD AND ELECTRONIC DEVICE INCLUDING THE SAME

(71) Applicant: Samsung Electronics Co., Ltd., Suwon-si (KR)

(72) Inventors: Seungyoon JUNG, Suwon-si (KR); Woncheol LEE, Suwon-si (KR); Seongjung KIM, Suwon-si (KR); Youngki LEE, Suwon-si (KR); Dongkwon CHOI, Suwon-si (KR)

(73) Assignee: Samsung Electronics Co., Ltd., Suwon-si (KR)

(21) Appl. No.: 19/633,460

(22) Filed: Mar. 30, 2026

(30) Foreign Application Priority Data
Apr. 2, 2025 (KR) 10-2025-0043048

(51) Int. Cl. H01P 5/107; H01P 1/16; H01P 3/12; H05K 1/11

(52) U.S. Cl. CPC H01P 5/107; H01P 1/16; H01P 3/12; H05K 1/115; H05K 2201/037; H05K 2201/09609; H05K 2201/09985

(57) ABSTRACT

A signal transmission structure including a multi-layer circuit board, a transition structure and cavity structure, the layers including a ground plane and a transmission line, and a waveguide, the transition structure includes a metal plane included in at least one of the layers, a first via electrically connecting the transmission line to the metal plane, and a second via electrically connecting the ground plane to the metal plane, the transition structure is configured to mode-convert a first signal transmitted through the transmission line into a second signal, the cavity structure is configured such that a plurality of vias surrounding side surfaces of the transition structure form side surfaces of the cavity structure, and the waveguide is on an upper surface of a topmost layer among the layers, the waveguide being connected to the cavity structure, and the waveguide being configured to propagate the second signal.

### CROSS-REFERENCE TO RELATED APPLICATION

This application is based on and claims priority under 35 U.S.C. § 119 to Korean Patent Application No. 10-2025-0043048, filed on Apr. 2, 2025, in the Korean Intellectual Property Office, the disclosure of which is incorporated by reference herein in its entirety.

### BACKGROUND

The inventive concepts relate to a signal transmission structure for signal transmission in a multilayered circuit board and an electronic device including the signal transmission structure.

A recent fifth generation (5G) (or New Radio (NR)) communication system is new radio access technology and aims to provide ultra-high-speed data services of several Gbps by using an ultra-wideband of at least 100 MHz, which is wider than those of existing Long Term Evolution (LTE) and LTE-A. However, signals having higher frequencies (e.g., mmWave or Terahertz) experience substantial loss during transmission.

A waveguide exhibiting lower transmission loss may be used to reduce the loss of higher-frequency signals (e.g., mmWave or Terahertz). However, when a transition structure for converting signals propagating through a transmission line included in a multi-layer circuit board (e.g., a Printed Circuit Board (PCB)) and guiding the converted signals into a waveguide takes the form of a patch antenna on a substrate or is implemented through waveguide machining, the waveguide may be connected only in a direction perpendicular to the propagation direction of the transmission line, or the volume of the waveguide may increase.

### SUMMARY

The inventive concepts provide a signal transmission structure that enables mode conversion of signals, which are transmitted through transmission lines of a multi-layer circuit board, by using a transition structure implemented using metals and vias in the multi-layer circuit board, and then guides the mode-converted signals into a waveguide, and also provides an electronic device including the signal transmission structure.

According to an aspect of the inventive concepts, there is provided a signal transmission structure including a first multi-layer circuit board including a plurality of layers, a transition structure and cavity structure, the plurality of layers including a ground plane and a first transmission line, and a waveguide, the transition structure includes a first metal plane included in at least one of the plurality of layers, a first via electrically connecting the first transmission line to the first metal plane, and a second via electrically connecting the ground plane to the first metal plane, the transition structure is configured to mode-convert a first signal transmitted through the first transmission line into a second signal, the cavity structure is configured such that a plurality of vias surrounding side surfaces of the transition structure form side surfaces of the cavity structure, and the waveguide is on an upper surface of a topmost layer among the plurality of layers, the waveguide being connected to the cavity structure, and the waveguide being configured to propagate the second signal.

According to an aspect of the inventive concepts, there is provided a signal transmission structure including a ground plane, a first transmission line, a transition structure, a cavity structure, and a waveguide, the transition structure electrically connects the first transmission line to a first metal plane included in at least one of a plurality of layers of a multi-layer circuit board, the transition structure being configured to form a loop by electrically connecting the ground plane to the first metal plane, and the transition structure being configured to mode-convert a first signal transmitted through the first transmission line along the loop into a second signal, the cavity structure is configured such that a plurality of vias surrounding side surfaces of the transition structure form side surfaces of the cavity structure, and the waveguide is on an upper surface of a topmost layer among the plurality of layers, the waveguide being connected to the cavity structure, and the waveguide being configured to propagate the second signal.

According to an aspect of the inventive concepts, there is provided an electronic device including a communication circuit including a multi-layer circuit board and a waveguide, the multi-layer circuit board including a plurality of layers, a transition structure and a cavity structure, and the plurality of layers including a ground plane and a first transmission line, and processing circuitry configured to execute an instruction based on a signal received from the communication circuit, the transition structure electrically connects the first transmission line to a first metal plane included in at least one of the plurality of layers, the transition structure electrically connecting the ground plane to the first metal plane, the transition structure being configured to form a loop according to a first signal transmitted through the first transmission line, and the transition structure being configured to mode-convert the first signal into a second signal along the loop, the cavity structure is configured such that a plurality of vias surrounding side surfaces of the transition structure form side surfaces of the cavity structure, and the waveguide is on an upper surface of a topmost layer among the plurality of layers, the waveguide being connected to the cavity structure, and the waveguide being configured to propagate the second signal.

### BRIEF DESCRIPTION OF THE DRAWINGS

Embodiments will be more clearly understood from the following detailed description taken in conjunction with the accompanying drawings in which:

FIG. 1 illustrates a signal transmission structure according to embodiments;

FIG. 2 is a diagram illustrating the signal transmission structure of FIG. 1 as viewed in a direction perpendicular to an upper surface of a multi-layer circuit board, according to embodiments;

FIG. 3 illustrates a signal transmission structure according to a Comparative Example;

FIG. 4 illustrates a signal transmission structure according to embodiments;

FIG. 5 illustrates a signal transmission structure according to embodiments;

FIG. 6 illustrates a signal transmission structure according to embodiments;

FIG. 7 illustrates a signal transmission structure according to embodiments;

FIGS. 8 and 9 are diagrams illustrating the signal transmission structure of FIG. 7 from different angles, according to embodiments;

FIG. 10 illustrates a signal transmission structure according to embodiments;

FIG. 11 illustrates a signal transmission structure according to embodiments;

FIG. 12 illustrates a signal transmission structure according to embodiments;

FIG. 13 illustrates transmission lines according to embodiments;

FIG. 14 is a block diagram of an electronic device according to embodiments; and

FIG. 15 is a conceptual view illustrating an Internet of Things (IoT) network system to which embodiments are applied.

### DETAILED DESCRIPTION

Hereinafter, embodiments are described in detail with reference to the attached drawings.

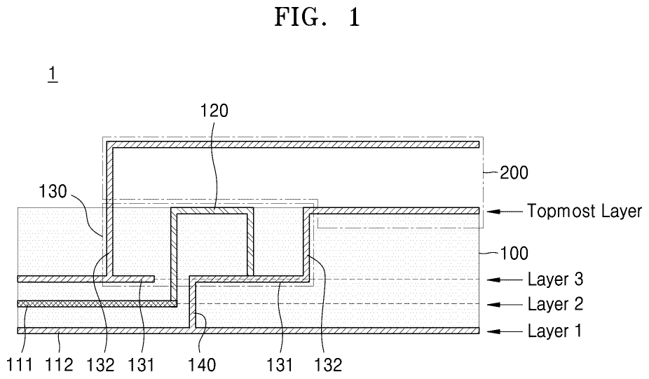

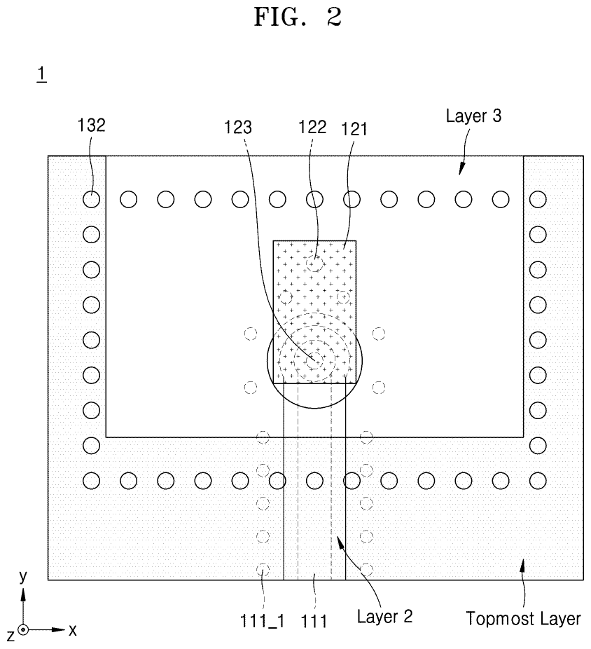

FIG. 1 illustrates a signal transmission structure 1 according to embodiments. FIG. 2 is a diagram illustrating the signal transmission structure 1 of FIG. 1 as viewed in a direction perpendicular to an upper surface of a multi-layer circuit board 100, according to embodiments.

Referring to FIGS. 1 and 2, the signal transmission structure 1 is a three-dimensional structure and may be represented using a Cartesian coordinate system. For example, in the Cartesian coordinate system, the x axis, y axis, and z axis may be mutually orthogonal, each forming a 90-degree angle with the others. FIG. 1 may illustrate the signal transmission structure 1 as viewed in a direction perpendicular to the plane formed by the y and z axes (or a direction perpendicular to the side surfaces of the signal transmission structure 1), and FIG. 2 may illustrate the signal transmission structure 1 as viewed in a direction perpendicular to the plane formed by the y and x axes (or a direction perpendicular to the upper surface of the multi-layer circuit board 100). In addition, the signal transmission structure 1 may be applied to a signal transmission circuit. The signal transmission structures described below may also be applied to a signal transmission circuit.

Referring to FIG. 1, the signal transmission structure 1 may include the multi-layer circuit board 100 and/or a waveguide 200. The multi-layer circuit board 100 may include a plurality of layers and be filled with dielectrics (e.g., areas of the multi-layer circuit board 100 not including metals or vias may be filed by a dielectric material). In the following description, the multi-layer circuit board 100 includes four layers, that is, a first layer Layer 1, a second layer Layer 2, a third layer Layer 3, and a topmost layer Topmost Layer, but embodiments are not limited thereto. For example, the multi-layer circuit board 100 may further include layers in addition to the four layers. The multi-layer circuit board may be a Printed Circuit Board (PCB).

In embodiments, the first layer Layer 1 may include a ground plane 112. For example, the ground plane 112 may correspond to the entire first layer Layer 1 or a portion of the first layer Layer 1. Alternatively, the ground plane 112 may correspond to a ground line.

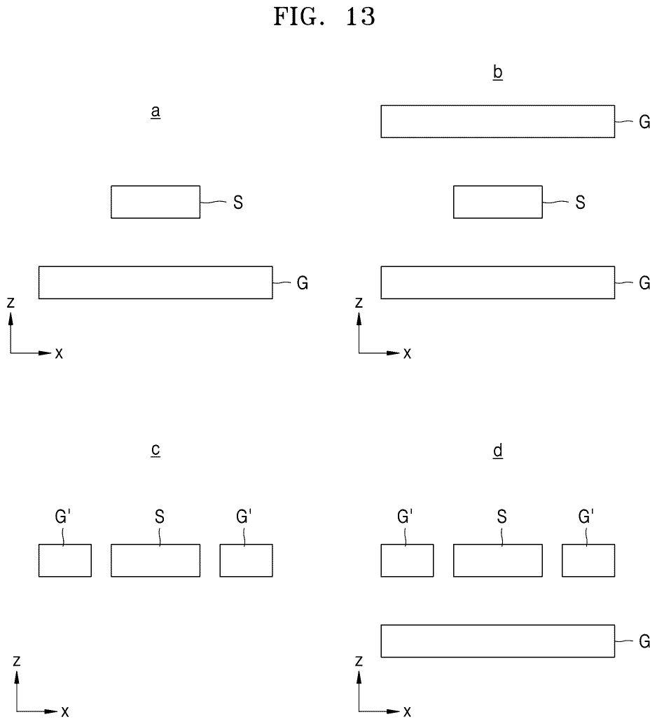

In embodiments, the second layer Layer 2 may include a first transmission line 111. The first transmission line 111 may refer to a line configured to transmit a signal. For example, the first transmission line 111 may include at least one of a microstrip, a stripline, a Co-Planar Waveguide (CPW), and/or a Grounded Co-Planar Waveguide (GCPW). Specific examples of each transmission line and a ground conductor 111_1 of FIG. 2 are described below with reference to FIG. 13.

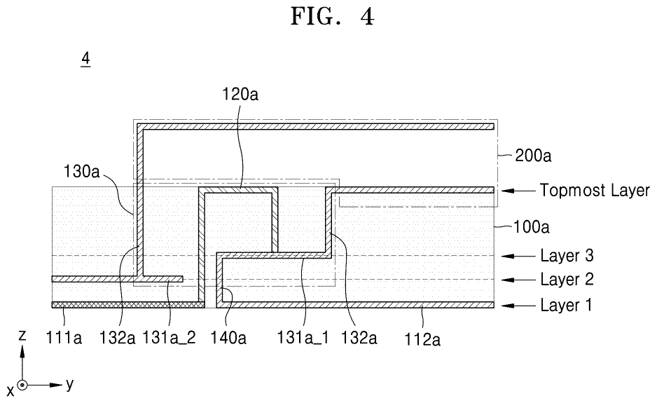

In embodiments, the ground plane 112 may be on a different layer from the first transmission line 111. For example, the topmost layer Topmost Layer may refer to the uppermost layer among the layers of the multi-layer circuit board 100, and the second layer Layer 2 including the first transmission line 111 may be positioned closer to the topmost layer Topmost Layer than the first layer Layer 1 including the ground plane 112. However, embodiments are not limited thereto, and the ground plane 112 and the first transmission line 111 may be placed on the same layer (or similar layers). This will be described in more detail with reference to FIG. 4.

The multi-layer circuit board 100 may include a transition structure 120. The transition structure 120 may refer to a structure configured to perform mode conversion of signals transmitted through transmission lines. For example, the transition structure 120 may be a structure configured to perform mode conversion of a first signal transmitted through the first transmission line 111 (e.g., a signal transmitted in a Transverse ElectroMagnetic (TEM) mode) into a second signal (e.g., a signal transmitted in a Transverse Electric (TE) 10 mode).

The transition structure 120 may be implemented using metals and vias in the multi-layer circuit board 100. In embodiments, the transition structure 120 may form a loop by using the metals and vias in the multi-layer circuit board 100 and may be configured to mode-convert a first signal transmitted through the first transmission line 111 along the loop into a second signal.

As shown in FIG. 2, for example, the transition structure 120 of FIG. 1 may include a first metal plane 121 included in at least one of the layers in the multi-layer circuit board 100 of FIG. 1, a first via 123 electrically connecting the first transmission line 111 to the first metal plane 121, and a second via 122 electrically connecting the ground plane 112 of FIG. 1 to the first metal plane 121. The transition structure 120 of FIG. 1 may form a loop from the first transmission line 111 to the ground plane 112 of FIG. 1 by using the first metal plane 121, the first via 123, and the second via 122 and may mode-convert the first signal transmitted through the first transmission line 111 along the loop into a second signal, thereby propagating (or radiating) the second signal into the waveguide 200.

Because the transition structure 120 according to embodiments may be implemented using the metals and vias in the multi-layer circuit board 100, the transition structure 120 may be relatively easily manufactured and implemented with a relatively small volume.

FIG. 2 illustrates that the first metal plane 121 is arranged on the topmost layer Topmost Layer, but is not limited thereto. For example, the first metal plane 121 may be arranged on a layer other than the topmost layer Topmost Layer among the layers of the multi-layer circuit board 100.

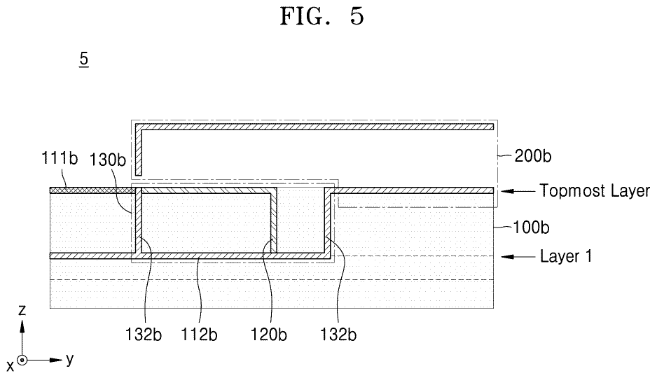

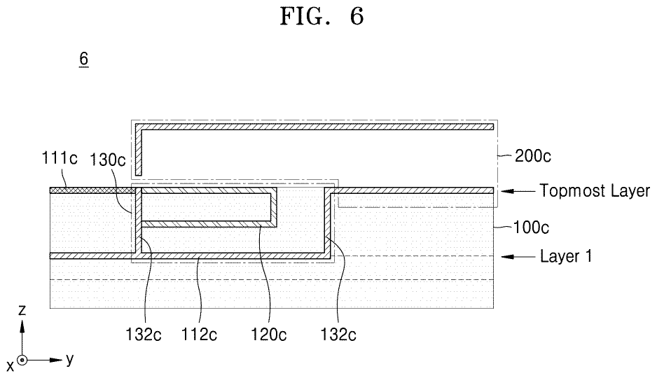

The second via 122 may electrically connect the ground plane 112 of FIG. 1 to the first metal plane 121 through a third via 140 electrically connecting the ground plane 112 of FIG. 1 to a second metal plane 131 of FIG. 1, but embodiments are not limited thereto. For example, the second via 122 may directly connect the ground plane 112 to the first metal plane 121, and specific examples thereof are described below with reference to FIGS. 5 and 6.

Referring back to FIG. 1, the multi-layer circuit board 100 may include a cavity structure 130. The cavity structure 130 may refer to a structure configured to propagate (or radiate) a signal, which is propagated (or radiated) by the transition structure 120, into the waveguide 200.

In embodiments, the cavity structure 130 may be configured to surround the side surfaces of the transition structure 120, block signals propagating (or radiating) in a lateral direction of the transition structure 120 (e.g., a direction parallel to the xy plane), and allow signals propagating (or radiating) in a direction from the lower surface of the transition structure 120 to the upper surface thereof (e.g., the z-axis direction) to pass, thereby guiding the propagation (or radiation) of the signals into the waveguide 200.

Referring to FIG. 2, for example, a plurality of vias 132 surrounding the side surfaces of the transition structure 120 form the side surfaces of the cavity structure 130 of FIG. 1. The vias 132 may electrically connect between the third layer Layer 3 and the topmost layer Topmost Layer.

Referring back to FIG. 1, in embodiments, the cavity structure 130 may be configured such that a metal plane included in at least one of the layers of the multi-layer circuit board 100 forms the lower surface of the cavity structure 130.

For example, the second metal plane 131 may be configured to form the lower surface of the cavity structure 130. The third layer Layer 3 arranged between the second layer Layer 2 and the topmost layer Topmost Layer of the multi-layer circuit board 100 may include the second metal plane 131.

In the cavity structure 130, signals propagating (or radiating) in the lateral direction of the transition structure 120 after the mode conversion by the transition structure 120 may be blocked by the vias 132, and signals propagating (or radiating) in the direction from the upper surface of the transition structure 120 to the lower surface of the transition structure 120 after the mode conversion may be blocked by the second metal plane 131. Accordingly, the cavity structure 130 may allow signals, which propagate (or radiate) from the lower surface of the transition structure 120 to the upper surface of the transition structure 120 after the mode conversion by the transition structure 120, to pass and guide the propagation (or radiation) of the signals from the transition structure 120 into the waveguide 200.

The waveguide 200 may refer to a transmission medium for transmitting signals (e.g., electromagnetic waves) from one location to another location, have a closed structure including metal or dielectrics, and transmit signals through reflection or interference of electromagnetic waves in the waveguide 200. In embodiments, the waveguide 200 may be in various forms. For example, the waveguide 200 may be formed in a rectangular shape including metal, a circular shape including metal, or a shape including a dielectric material. Hereinafter, the waveguide 200 is described as a rectangular waveguide including metal.

In embodiments, the waveguide 200 may be arranged on the upper surface of the multi-layer circuit board 100 (e.g., the upper surface of the topmost layer Topmost Layer) and connected to the cavity structure 130. The waveguide 200 may be filled with air and configured to propagate (or radiate) the second signal, which is received from the transition structure 120, in a direction parallel to the propagation direction of the first transmission line 111 (e.g., the y-axis direction from the left side of the multi-layer circuit board 100 to the right side of the multi-layer circuit board 100).

For example, the metal plane may be configured to form the entire upper surface and a portion of the lower surface of the waveguide 200, and another portion of the lower surface of the waveguide 200 may face the upper surface of the multi-layer circuit board 100 and the upper surface of the transition structure 120 (e.g., the first metal plane 121 of FIG. 2). In this region, the metal plane may be omitted. The upper surface of the waveguide 200 may extend in the y-axis direction.

For example, the waveguide 200 may be configured such that a plurality of vias form the side surfaces of the waveguide 200, and some of the vias may be connected to the vias forming the side surfaces of the cavity structure 130 (e.g., the vias 132 of FIG. 2).

For example, the waveguide 200 may be configured such that a plurality of vias form the side surfaces of the waveguide 200, and some of the vias may surround the vias forming the side surfaces of the cavity structure 130 (e.g., the vias 132 of FIG. 2).

In embodiments, the waveguide 200 may be a Substrate-Based Waveguide (SBW). For example, some portions of the waveguide 200 may be formed within the multi-layer circuit board 100, and the interior of the waveguide 200 may be filled with dielectrics so that the structure of the waveguide 200 may be the same as (or similar to) that of the cavity structure 130. Other portions of the waveguide 200 may be arranged on the upper surface of the multi-layer circuit board 100, and the interior of the waveguide 200 may be filled with air. The waveguide 200 may be configured to propagate (or radiate) the second signal, which is received from the transition structure 120, in a direction parallel to the propagation direction of the first transmission line 111 (e.g., the y-axis direction from the left side of the multi-layer circuit board 100 to the right side thereof). According to embodiments, for example, the waveguide 200 may be configured to propagate (or radiate) the second signal in a direction perpendicular to an upper surface of the topmost layer Topmost Layer. In this case, the cavity structure 130 may not be separately formed, and the function of the cavity structure 130 may instead be performed by the structure of the waveguide 200.

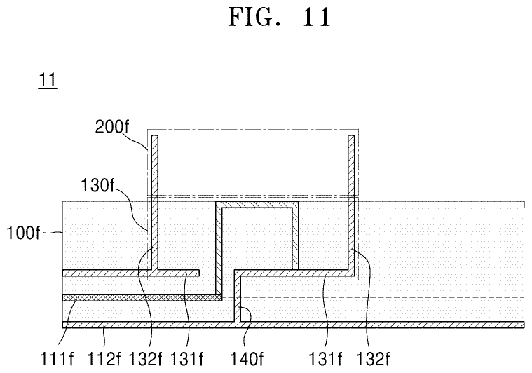

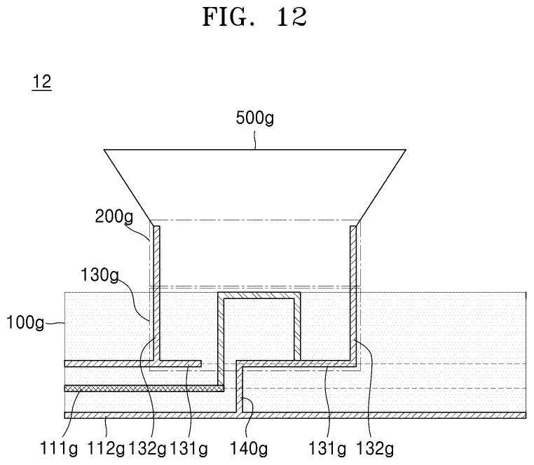

The waveguide 200 according to embodiments may propagate (or radiate) signals in directions both perpendicular and parallel to the propagation direction of the first transmission line 111 through the transition structure 120 and the cavity structure 130. A specific example, in which the waveguide 200 propagates (or radiates) signals in the direction perpendicular to the propagation direction of the first transmission line 111, is described with reference to FIGS. 11 and 12.

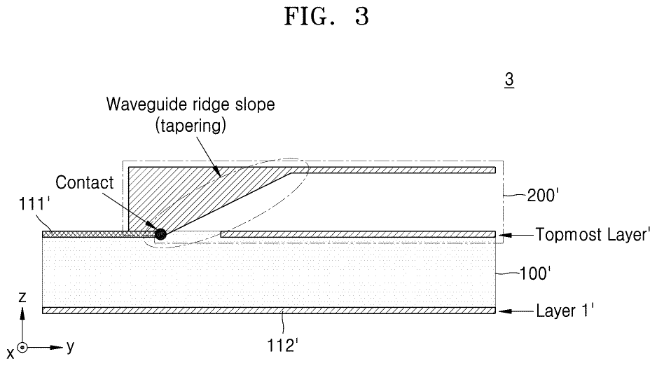

FIG. 3 illustrates a signal transmission structure 3 according to a Comparative Example.

Referring to FIG. 3, the signal transmission structure 3 according to the Comparative Example may include a multi-layer circuit board 100′ and a waveguide 200′. The multi-layer circuit board 100′ may include a first layer Layer 1′ including a ground plane 112′ and a topmost layer Topmost Layer′ including a transmission line 111′.

The signal transmission structure 3 according to the Comparative Example may implement a transition structure for propagating (or radiating) signals, which are transmitted through the transmission line 111′, into the waveguide 200′ through interior machining (e.g., tapering) of the waveguide 200′. For mode conversion, the signal transmission structure 3 according to the Comparative Example may require (or otherwise, use) a ridge of the waveguide 200′ that has an inclined surface. In this case, interior machining of the waveguide 200′ may be necessary (or otherwise, used) to form the ridge, and the volume of the waveguide 200′ may be increased to implement the inclined surface.

In contrast, the signal transmission structure (e.g., the signal transmission structure 1 shown in FIGS. 1 and 2) of the inventive concepts may further include the transition structure (e.g., the transition structure 120 of FIG. 1) implemented using the metals and vias in the multi-layer circuit board (e.g., the multi-layer circuit board 100 of FIG. 1) so that additional machining of the waveguide (e.g., the waveguide 200 of FIG. 1) may not be required (or used).

Moreover, because the multi-layer circuit board (e.g., the multi-layer circuit board 100 of FIG. 1) is filled with dielectrics, the permittivity of the dielectrics may be higher than air, and the transition structure (e.g., the transition structure 120 of FIG. 1) of the inventive concepts may have a smaller volume than the ridge structure according to the Comparative Example based on the permittivity.

FIG. 4 illustrates a signal transmission structure 4 according to embodiments. In embodiments, the signal transmission structure 4 may be an example of the signal transmission structure 1 of FIGS. 1 and 2, and a waveguide 200a may be the same as (or similar to) the waveguide 200 of FIG. 1. FIG. 4 illustrates the signal transmission structure 4 as viewed in the same direction as (or a similar direction to) the signal transmission structure 1 of FIG. 1. The descriptions provided with reference to FIGS. 1 and 2 are not repeated.

Referring to FIG. 4, the signal transmission structure 4 may include a multi-layer circuit board 100a and/or the waveguide 200a. The multi-layer circuit board 100a may include multiple layers and be filled with dielectrics (e.g., areas of the multi-layer circuit board 100a not including metals or vias may be filed by a dielectric material).

In embodiments, a first layer Layer 1 may include a ground plane 112a and a first transmission line 111a. For example, the ground plane 112a and the first transmission line 111a may be on the same layer (or a similar layer) but may not overlap each other (the ground plane 112a and the first transmission line 111a may not overlap).

The multi-layer circuit board 100a may include a transition structure 120a. In embodiments, the transition structure 120a may form a loop by using metals and vias in the multi-layer circuit board 100a and may be configured to mode-convert a first signal transmitted through the first transmission line 111a along the loop into a second signal. For example, the transition structure 120a may include vias (e.g., a via electrically connecting the topmost layer Topmost Layer and the first layer Layer 1 and a via electrically connecting the topmost layer Topmost Layer and the third layer Layer 3) and a metal plane (e.g., a metal plane of the topmost layer Topmost Layer). The transition structure 120a may electrically connect the first transmission line 111a to the metal plane (e.g., the metal plane of the topmost layer Topmost Layer) through the via (e.g., the via electrically connecting the topmost layer Topmost Layer and the first layer Layer 1), and may electrically connect the metal plane (e.g., the metal plane of the topmost layer Topmost Layer) to a second metal plane 131a_1 through the via (e.g., the via electrically connecting the topmost layer Topmost Layer and the third layer Layer 3). Based on this configuration, the transition structure 120a may be electrically connected to the first transmission line 111a and the second metal plane 131a_1. Through a third via 140a electrically connecting the second metal plane 131a_1 to the ground plane 112a, the second metal plane 131a_1 may be electrically connected to the ground plane 112a, and thus, the transition structure 120a may form a loop from the first transmission line 111a to the ground plane 112a.

The multi-layer circuit board 100a may include a cavity structure 130a. In embodiments, the cavity structure 130a may be configured such that vias 132a surrounding the side surfaces of the transition structure 120a form the side surfaces of the cavity structure 130a. Some of the vias 132a may electrically connect between the third layer Layer 3 and the topmost layer Topmost Layer, and others thereof may electrically connect the second layer Layer 2 and the topmost layer Topmost Layer.

In embodiments, a metal plane included in at least one of the layers of the multi-layer circuit board 100a may be configured to form the lower surface of the cavity structure 130a.

For example, the cavity structure 130a may be configured such that the second metal plane 131a_1 and a third metal plane 131a_2 form the lower surface of the cavity structure 130a. The third layer Layer 3 among the layers of the multi-layer circuit board 100a may include the second metal plane 131a_1 and may be relatively closer to the topmost layer Topmost Layer than the second layer Layer 2 including the third metal plane 131a_2.

In the cavity structure 130a, signals propagating (or radiating) in the lateral direction of the transition structure 120a after the mode conversion by the transition structure 120a may be blocked by the vias 132a, and signals propagating (or radiating) in the direction from the upper surface of the transition structure 120a to the lower surface thereof after the mode conversion may be blocked by the second metal plane 131a_1 and the third metal plane 131a_2. Accordingly, the cavity structure 130a may allow signals, which propagate (or radiate) from the lower surface of the transition structure 120a to the upper surface thereof after the mode conversion by the transition structure 120a, to pass and guide the propagation (or radiation) of the signals from the transition structure 120a into the waveguide 200a.

FIG. 5 illustrates a signal transmission structure 5 according to embodiments. In embodiments, the signal transmission structure 5 may be an example of the signal transmission structure 1 of FIGS. 1 and 2, and a waveguide 200b may be the same as (or similar to) the waveguide 200 of FIG. 1. FIG. 5 illustrates the signal transmission structure 5 as viewed in the same direction as (or a similar direction to) the signal transmission structure 1 of FIG. 1. The descriptions provided with reference to FIGS. 1 and 2 are not repeated.

Referring to FIG. 5, the signal transmission structure 5 may include a multi-layer circuit board 100b and/or the waveguide 200b. The multi-layer circuit board 100b may include multiple layers and be filled with dielectrics (e.g., areas of the multi-layer circuit board 100b not including metals or vias may be filed by a dielectric material). In embodiments, a first layer Layer 1 may include a ground plane 112b, and a topmost layer Topmost Layer may include a first transmission line 111b.

The multi-layer circuit board 100b may include a transition structure 120b. In embodiments, the transition structure 120b may form a loop by using metals and vias in the multi-layer circuit board 100b and may be configured to mode-convert a first signal transmitted through the first transmission line 111b along the loop into a second signal. For example, the transition structure 120b may include a via (e.g., a via electrically connecting the topmost layer Topmost Layer to the first layer Layer 1) and a metal plane (e.g., a metal plane of the topmost layer Topmost Layer). The transition structure 120b may electrically connect the first transmission line 111b to a metal plane (e.g., the metal plane included in the topmost layer Topmost Layer) through the via or directly. The transition structure 120b may electrically connect a metal plane (e.g., the metal plane included in the topmost layer Topmost Layer) to the ground plane 112b through a via (e.g., the via electrically connecting the topmost layer Topmost Layer to the first layer Layer 1) and may electrically connect the first transmission line 111b to the ground plane 112b based on the above connection, thereby forming a loop.

The multi-layer circuit board 100b may include a cavity structure 130b. In embodiments, the cavity structure 130b may be configured such that vias 132b surrounding the side surfaces of the transition structure 120b form the side surfaces of the cavity structure 130b. The vias 132b may electrically connect between the first layer Layer 1 and the topmost layer Topmost Layer. In embodiments, the ground plane 112b may be configured to form the lower surface of the cavity structure 130b.

In the cavity structure 130b, signals propagating (or radiating) in the lateral direction of the transition structure 120b after the mode conversion by the transition structure 120b may be blocked by the vias 132b, and signals propagating (or radiating) in the direction from the upper surface of the transition structure 120b to the lower surface thereof after the mode conversion may be blocked by the ground plane 112b. Accordingly, the cavity structure 130b may allow signals, which propagate (or radiate) from the lower surface of the transition structure 120b to the upper surface thereof after the mode conversion by the transition structure 120b, to pass and guide the propagation (or radiation) of the signals from the transition structure 120b into the waveguide 200b.

FIG. 6 illustrates a signal transmission structure 6 according to embodiments. In embodiments, the signal transmission structure 6 may be an example of the signal transmission structure 1 of FIGS. 1 and 2, and a waveguide 200c may be the same as (or similar to) the waveguide 200 of FIG. 1. FIG. 6 illustrates the signal transmission structure 6 as viewed in the same direction as (or a similar direction to) the signal transmission structure 1 of FIG. 1. The descriptions provided with reference to FIGS. 1 and 2 are not repeated.

Referring to FIG. 6, the signal transmission structure 6 may include a multi-layer circuit board 100c and/or the waveguide 200c. The multi-layer circuit board 100c may include multiple layers and be filled with dielectrics (e.g., areas of the multi-layer circuit board 100c not including metals or vias may be filed by a dielectric material). In embodiments, a first layer Layer 1 may include a ground plane 112c, and a topmost layer Topmost Layer may include a first transmission line 111c.

The multi-layer circuit board 100c may include a transition structure 120c. In embodiments, the transition structure 120c may form a loop by using metals and vias in the multi-layer circuit board 100c and may be configured to mode-convert a first signal transmitted through the first transmission line 111c along the loop into a second signal. For example, the transition structure 120c may include a via (e.g., a via electrically connecting the topmost layer Topmost Layer to a layer arranged between the first layer Layer 1 and the topmost layer Topmost Layer) and metal planes (e.g., a metal plane included in the topmost layer Topmost Layer and a metal plane included in the layer arranged between the first layer Layer 1 and the topmost layer Topmost Layer). The transition structure 120c may electrically connect the first transmission line 111c to a metal plane (e.g., the metal plane included in the topmost layer Topmost Layer) through the via or directly. The transition structure 120c may electrically connect a metal plane (e.g., the metal plane included in the topmost layer Topmost Layer) to a metal plane (e.g., the metal plane included in the layer between the first layer Layer 1 and the topmost layer Topmost Layer) through a via (e.g., the via electrically connecting the topmost layer Topmost Layer to the layer between the first layer Layer 1 and the topmost layer Topmost Layer). A third via 132c may electrically connect the metal plane (the metal plane included in the layer between the first layer Layer 1 and the topmost layer Topmost Layer) to the ground plane 112c, and based on this connection, the transition structure 120c may electrically connect the first transmission line 111c to the ground plane 112c, thereby forming a loop.

The multi-layer circuit board 100c may include a cavity structure 130c. In embodiments, a plurality of vias 132c surrounding the side surfaces of the transition structure 120c may be configured to form the side surfaces of the cavity structure 130c. The vias 132c may electrically connect between the first layer Layer 1 and the topmost layer Topmost Layer. In embodiments, the ground plane 112c may be configured to form the lower surface of the cavity structure 130c.

In the cavity structure 130c, signals propagating (or radiating) in the lateral direction of the transition structure 120c after the mode conversion by the transition structure 120c may be blocked by the vias 132c, and signals propagating (or radiating) in the direction from the upper surface of the transition structure 120c to the lower surface thereof after the mode conversion may be blocked by the ground plane 112c. Accordingly, the cavity structure 130c may allow signals, which propagate (or radiate) from the lower surface of the transition structure 120c to the upper surface thereof after the mode conversion by the transition structure 120c, to pass and guide the propagation (or radiation) of the signals from the transition structure 120c into the waveguide 200c.

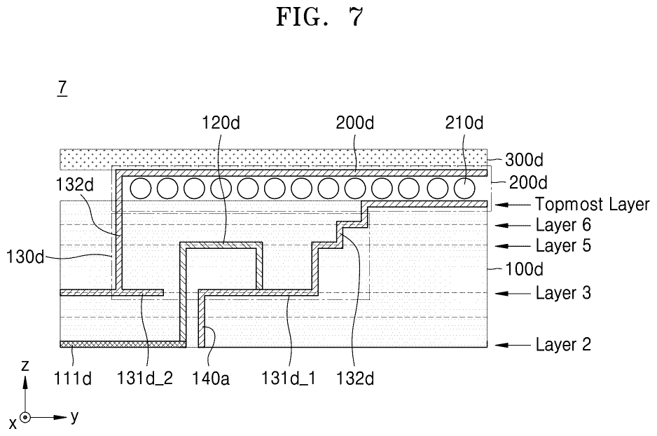

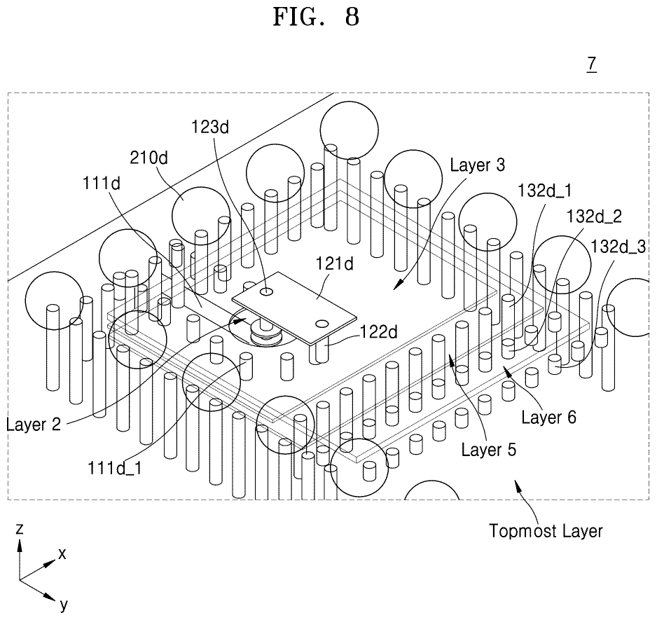

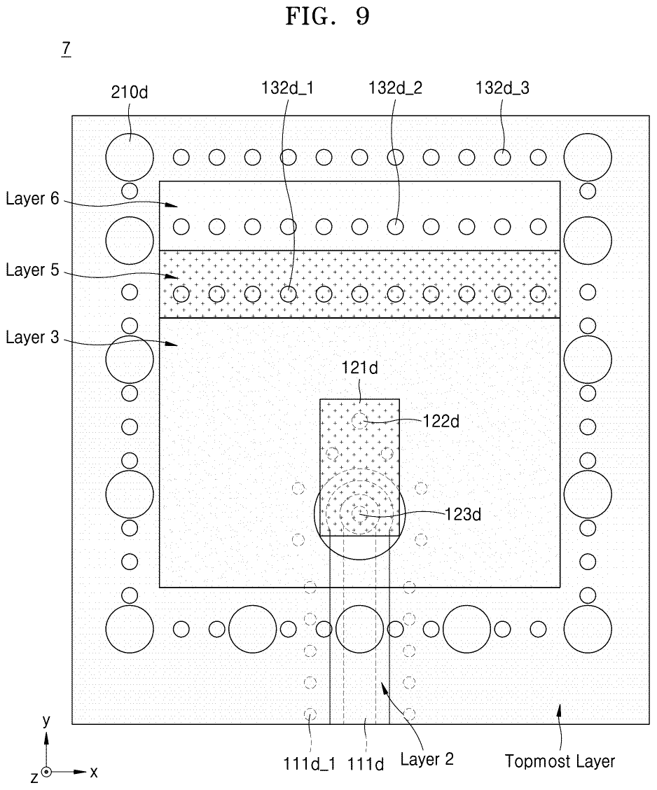

FIG. 7 illustrates a signal transmission structure 7 according to embodiments. FIGS. 8 and 9 are diagrams illustrating the signal transmission structure 7 of FIG. 7 from different angles, according to embodiments.

In embodiments, the signal transmission structure 7 of FIGS. 7 to 9 may be an example of the signal transmission structure 1 of FIGS. 1 and 2. FIG. 7 illustrates the signal transmission structure 7 of FIG. 7 as viewed in the same direction as (or a similar direction to) the signal transmission structure 1 of FIG. 1, FIG. 8 may be a perspective view of the signal transmission structure 7 of FIG. 7, and FIG. 9 illustrates the signal transmission structure 7 as viewed in the same direction as (or a similar direction to) the signal transmission structure 1 of FIG. 2. The descriptions provided with reference to FIGS. 1 and 2 are not repeated.

Referring to FIG. 7, the signal transmission structure 7 may include a multi-layer circuit board 100d, a waveguide 200d, and/or a substrate 300d. The multi-layer circuit board 100d may include multiple layers and be filled with dielectrics (e.g., areas of the multi-layer circuit board 100d not including metals or vias may be filed by a dielectric material). In embodiments, a second layer Layer 2 may include a first transmission line 111d.

The multi-layer circuit board 100d may include a transition structure 120d. In embodiments, the transition structure 120d may form a loop by using metals and vias in the multi-layer circuit board 100d and may be configured to mode-convert a first signal transmitted through the first transmission line 111d along the loop into a second signal. For example, the transition structure 120d may include vias (e.g., a via electrically connecting a fifth layer Layer 5 to the second layer Layer 2 and a via electrically connecting the fifth layer Layer 5 to a third layer Layer 3) and a metal plane (e.g., a metal plane included in the fifth layer Layer 5). The transition structure 120d may electrically connect the first transmission line 111d to a metal plane (e.g., the metal plane included in the fifth layer Layer 5) through a via (e.g., the via electrically connecting the fifth layer Layer 5 to the second layer Layer 2) and may electrically connect a metal plane (e.g., the metal plane included in the fifth layer Layer 5) to a second metal plane 131d_1 through a via (e.g., the via electrically connecting the fifth layer Layer 5 to the third layer Layer 3). Based on these connections, the transition structure 120d may be electrically connected to the first transmission line 111d and the second metal plane 131d_1. The second metal plane 131d_1 may be electrically connected to the substrate 300d through vias 132d and solder balls 210d, and the substrate 300d may correspond to the ground plane 112 of FIG. 1 and perform the same function (or a similar function). Based on this configuration, the second metal plane 131d_1 may be electrically connected to the substrate 300d, and the transition structure 120d may form a loop from the first transmission line 111d to the substrate 300d.

The multi-layer circuit board 100d may include a cavity structure 130d. In embodiments, the cavity structure 130d may be configured such that the vias 132d surrounding the side surfaces of the transition structure 120d form the side surfaces of the cavity structure 130d. Some of the vias 132d may electrically connect between the third layer Layer 3 and the topmost layer Topmost Layer. Others thereof may be arranged in a stepped structure to distance from the transition structure 120d as the vias 132d extend to upper layers of the multi-layer circuit board 100d, thus electrically connecting the third layer Layer 3 and the topmost layer Topmost Layer.

Referring to FIGS. 8 and 9, for example, a plurality of vias 132d_1 to 132d_3 arranged to the right (e.g., in the y-axis direction) with respect to the transition structure 120d may be arranged in a stepped structure. The vias 132d_1 may electrically connect the third layer Layer 3 to the fifth layer Layer 5 and extend in a direction (e.g., the y-axis direction) away (e.g., are directed away) from the transition structure 120d by using the metal plane included in the fifth layer Layer 5. The vias 132d_2 may electrically connect the fifth layer Layer 5 to a sixth layer Layer 6 and extend in the direction (e.g., the y-axis direction) away from the transition structure 120d by using a metal plane included in the sixth layer Layer 6. The vias 132d_3 may electrically connect the sixth layer Layer 6 to the waveguide 200d. When the cavity structure 130d is arranged in a stepped structure, impedance matching between the first transmission line 111d and the waveguide 200d may be relatively facilitated. FIGS. 8 and 9 illustrate that some vias 132d_1 to 132d_3 among the vias 132d are arranged in a stepped structure, but embodiments are not limited thereto. For example, all of the vias 132d may be arranged in a stepped structure, a greater number of vias than the vias 132d_1 to 132d_3 may be arranged in a stepped structure, and fewer vias than the vias 132d_1 to 132d_3 may also be arranged in a stepped structure.

In embodiments, the cavity structure 130d may be configured such that a metal plane included in at least one of the layers of the multi-layer circuit board 100d forms the lower surface of the cavity structure 130d.

For example, the second metal plane 131d_1 may be configured to form the lower surface of the cavity structure 130d. The third layer Layer 3 among the layers of the multi-layer circuit board 100d may include the second metal plane 131d_1.

In the cavity structure 130d, signals propagating (or radiating) in the lateral direction of the transition structure 120d after the mode conversion by the transition structure 120d may be blocked by the vias 132d, and signals propagating (or radiating) in the direction from the upper surface of the transition structure 120d to the lower surface thereof after the mode conversion may be blocked by the second metal plane 131d_1. Accordingly, the cavity structure 130d may allow signals, which propagate (or radiate) from the lower surface of the transition structure 120d to the upper surface thereof after the mode conversion by the transition structure 120d, to pass and guide the propagation (or radiation) of the signals from the transition structure 120d into the waveguide 200d.

In embodiments, the waveguide 200d may include an inner region, and the inner region may be filled with air and include at least one solder ball 210d.

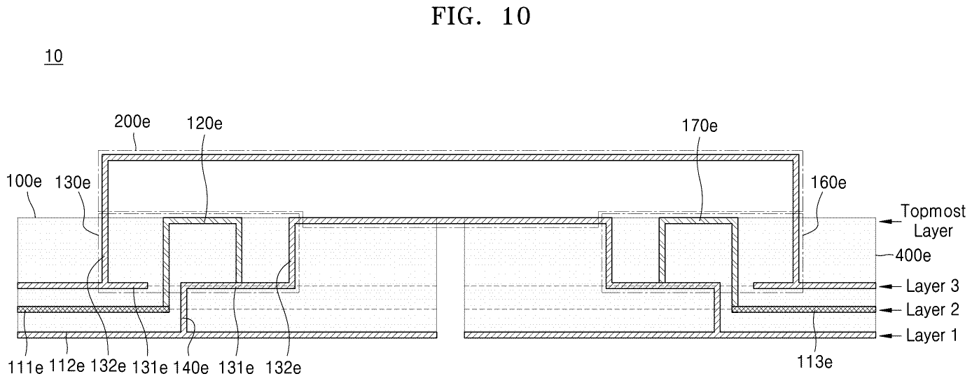

FIG. 10 illustrates a signal transmission structure 10 according to embodiments. In embodiments, the signal transmission structure 10 may be an example of the signal transmission structure 1 of FIGS. 1 and 2, and a multi-layer circuit board 100e and a waveguide 200e may be the same as (or similar to) the multi-layer circuit board 100 and the waveguide 200 of FIG. 1. The signal transmission structure 10 may be illustrated in a view taken in the same direction as (or a similar direction to) that of the signal transmission structure 1 of FIG. 1. The descriptions provided with reference to FIGS. 1 and 2 are not repeated.

A second multi-layer circuit board 400e may include a second transmission line 113e, a transition structure 170e, and/or a cavity structure 160e. The second transmission line 113e may refer to a line configured to transmit a signal.

The transition structure 170e may be the same as (or similar to) the transition structure (e.g., the transition structure 120 of FIG. 1) according to embodiments, and the cavity structure 160e may be the same as (or similar to) the cavity structure (e.g., the cavity structure 130 of FIG. 1) according to embodiments.

The waveguide 200e may connect the first multi-layer circuit board 100e to a second multi-layer circuit board 400e and propagate (or radiate) signals. For example, the waveguide 200e may receive a second signal by mode-converting a first signal, which is transmitted through the first transmission line 111e, via the transition structure 120e. The waveguide 200e may propagate (or radiate) the second signal to the transition structure 170e, and the transition structure 170e may mode-convert the second signal into a first signal and propagate (or radiate) the first signal to the second transmission line 113e. According to embodiments, a ground plane 112e, a transition structure 120e, a cavity structure 130e, a second metal plate 131e, a plurality of vias 132e and/or a third via 140e illustrated in FIG. 10 may be the same as or similar to the ground plane 112, the transition structure 120, the cavity structure 130, the second metal plate 131, the plurality of vias 132 and/or the third via 140 discussed in connection with FIG. 1.

FIG. 10 illustrates that the first multi-layer circuit board 100e has the same structure as (or a similar structure to) the second multi-layer circuit board 400e, but embodiments are not limited thereto. The first multi-layer circuit board 100e and the second multi-layer circuit board 400e may have different structures; for example, the first multi-layer circuit board 100e may correspond to the multi-layer circuit board 100a of FIG. 4, and the second multi-layer circuit board 400e may correspond to the multi-layer circuit board 100b of FIG. 5.

FIG. 11 illustrates a signal transmission structure 11 according to embodiments. In embodiments, the signal transmission structure 11 may be an example of the signal transmission structure 1 of FIGS. 1 and 2, and a multi-layer circuit board 100f may be the same as (or similar to) the multi-layer circuit board 100 of FIG. 1. The signal transmission structure 11 may be illustrated in a view taken in the same direction as (or a similar direction to) that of the signal transmission structure 1 of FIG. 1. The descriptions provided with reference to FIGS. 1 and 2 are not repeated.

A waveguide 200f may be arranged on the upper surface of the multi-layer circuit board 100f (e.g., an upper surface of a topmost layer Topmost Layer) and may be connected to a cavity structure 130f. The waveguide 200f may be filled with air and configured to propagate (or radiate) the second signal, which is received from a transition structure 120f, in the direction (e.g., the z-axis direction) parallel to the propagation direction of a first transmission line 111f (e.g., the y-axis direction from the left side of the multi-layer circuit board 100f to the right side of the multi-layer circuit board 100f).

For example, the side surfaces of the waveguide 200f may be formed by a metal plane or a plurality of vias, and some of the vias may be connected to a plurality of vias 132f forming the side surfaces of the cavity structure 130f. The side surfaces of the waveguide 200f may extend in the z-axis direction.

For example, the side surfaces of the waveguide 200f may be formed by the vias, and some of the vias may surround the vias 132f forming the side surfaces of the cavity structure 130f.

In embodiments, the waveguide 200f may be an SBW. For example, some portions of the waveguide 200f may be formed within the multi-layer circuit board 100f, and the interior of the waveguide 200f may be filled with dielectrics so that the structure of the waveguide 200f may be the same as (or similar to) that of the cavity structure 130f. Other portions of the waveguide 200f may be arranged on the upper surface of the multi-layer circuit board 100f, and the interior of the waveguide 200f may be filled with air. The waveguide 200f may propagate (or radiate) the second signal, which is received from the transition structure 120f, in a direction (e.g., the z-axis direction) perpendicular to the propagation direction of the first transmission line 111f (e.g., the y-axis direction from the left side to the right side of the multi-layer circuit board 100f). According to embodiments, for example, the waveguide 200f may be configured to propagate (or radiate) the second signal in a direction parallel to an upper surface of the topmost layer Topmost Layer. In this case, the cavity structure 130f may not be separately formed, and the function of the cavity structure 130f may instead be performed by the structure of the waveguide 200f. According to embodiments, a ground plane 112f, a second metal plate 131f, a plurality of vias 132f and/or a third via 140f illustrated in FIG. 11 may be the same as or similar to the ground plane 112, the second metal plate 131, the plurality of vias 132 and/or the third via 140 discussed in connection with FIG. 1.

FIG. 12 illustrates a signal transmission structure 12 according to embodiments. In embodiments, the signal transmission structure 12 may be an example of the signal transmission structure 10 of FIG. 10, and a multi-layer circuit board 100g and a waveguide 200g may be the same as (or similar to) the multi-layer circuit board 100f and the waveguide 200f of FIG. 10. The signal transmission structure 11 may be illustrated in a view taken in the same direction as (or a similar direction to) that of the signal transmission structure 10 of FIG. 10. The descriptions provided with reference to FIG. 10 are not repeated.

The waveguide 200g may connect between the multi-layer circuit board 100g and an antenna 500g. (may also be referred to herein as an antenna structure) In embodiments, the waveguide 200g may mode-convert a first signal, which is transmitted through a first transmission line 111g, into a second signal by using a transition structure 120g and may propagate (or radiate) the second signal to the antenna 500g.

FIG. 12 illustrates that the antenna 500g is a horn antenna, but the antenna 500g may vary. For example, the antenna 500g may include a horn antenna having a horn shape and extending from an aperture of a waveguide, a slot antenna that radiates signals through a plurality of slots formed in the surface of a waveguide, an aperture antenna that directly radiates electromagnetic waves through an aperture exposing a waveguide, a dipole antenna that transmits signals by converting a waveguide into a coaxial structure, a patch antenna that receives signals provided from a waveguide, or the like. According to embodiments, a first transmission line 111g, a ground plane 112g, a transition structure 120g, a cavity structure 130g, a second metal plate 131g, a plurality of vias 132g and/or a third via 140g illustrated in FIG. 12 may be the same as or similar to the first transmission line 111, the ground plane 112, the transition structure 120, the cavity structure 130, the second metal plate 131, the plurality of vias 132 and/or the third via 140 discussed in connection with FIG. 1.

FIG. 13 illustrates transmission lines according to embodiments.

In embodiments, transmission lines a to d may be examples of the first transmission line 111 of FIG. 1, and repeated descriptions thereof are omitted. FIG. 13 may be plan views of the transmission lines a to d, taken along the xz plane of FIG. 1.

Referring to FIGS. 1 and 13, the transmission line a may be a microstrip including a signal transmission conductor S located on an upper portion of a specific layer of a multi-layer circuit board and a ground plane G located under the specific layer.

For example, the signal transmission conductor S of the transmission line a may be located on the second layer Layer 2, and the ground plane G of the transmission line a may be on a layer lower than the second layer Layer 2 in the negative z-axis direction. For example, the signal transmission conductor S of the transmission line a may be on the second layer Layer 2, while the ground plane G of the transmission line a may be on the first layer Layer 1.

The transmission line b may be a stripline in which ground planes G are symmetrically arranged on and under a specific layer with respect to a signal transmission conductor S located on the specific layer of the multi-layer circuit board.

For example, the signal transmission conductor S of the transmission line b may be on the second layer Layer 2, and the ground planes G of the transmission line b may be symmetrically arranged on and under the second layer Layer 2 in the z-axis direction. For example, the signal transmission conductor S of the transmission line b may be located on the second layer Layer 2, and the ground planes G of the transmission line b may be symmetrically arranged on layers located above the first layer Layer 1 and the second layer Layer 2 in the z-axis direction.

The transmission line c may be a CPW in which a signal transmission conductor S is located on a specific layer of the multi-layer circuit board and ground conductors G′ are located on both sides of the signal transmission conductor S.

For example, the signal transmission conductor S of the transmission line c may be arranged on the second layer Layer 2, and the ground conductors G′ of the transmission line c may be arranged on the same layer (or a similar layer), that is, the second layer Layer 2, on both sides of the signal transmission conductor S of the transmission line c. For example, the signal transmission conductor S of the transmission line c may be located on the second layer Layer 2, and the ground conductors G′ of the transmission line c may be the ground conductors 111_1 of FIG. 2 and located on the same layer (or a similar layer), that is, the second layer Layer 2, on both sides of the signal transmission conductor S.

The transmission line d may be a GCPW in which the signal transmission conductor S is arranged on a specific layer of a multi-layer circuit board, ground conductors G′ are arranged on both sides of the signal transmission conductor S, and a ground plane G is located under the specific layer.

For example, the signal transmission conductor S of the transmission line d may be arranged on the second layer Layer 2, and the ground conductors G′ of the transmission line d may also be on the second layer Layer 2 on both sides of the signal transmission conductor S of the transmission line. The ground plane G of the transmission line d may be located on a lower layer than the second layer Layer 2 in the z-axis direction. For example, the signal transmission conductor S of the transmission line d may be located on the second layer Layer 2, and the ground conductors G′ of the transmission line d may be the ground conductors 111_1 of FIG. 2 and located on the same layer (or a similar layer), that is, the second layer Layer 2, on both sides of the signal transmission conductor S. The ground plane G of the transmission line d may be located on the first layer Layer 1.

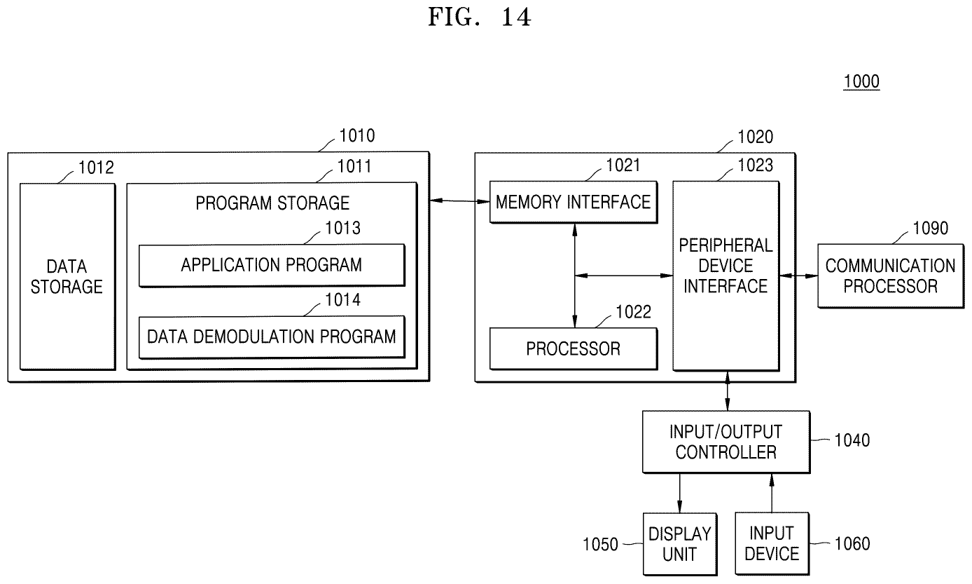

FIG. 14 is a block diagram of an electronic device according to embodiments.

Referring to FIG. 14, an electronic device 1000 may include a memory 1010, a processor unit 1020, an input/output controller 1040, a display unit 1050, an input device 1060, and/or a communication processor 1090. Here, there may be a plurality of memories 1010. Each component is described below.

The memory 1010 may include a program storage 1011 and/or a data storage 1012, wherein the program storage 1011 stores a program for controlling an operation of an electronic device, and the data storage 1012 stores data generated during the execution of the program. The data storage 1012 may store data required (or otherwise, used) for the operations of an application program 1013 and/or a data demodulation program 1014 or data generated by the operations thereof.

The program storage 1011 may include the application program 1013 and/or the data demodulation program 1014. Here, the programs included in the program storage 1011 may be represented as a set of instructions and referred to as an instruction set. The application program 1013 may include program code configured to execute various applications running on the electronic device 1000. In other words, the application program 1013 may include code (or commands) regarding the applications executable by a processor 1022.

The electronic device 1000 may include the communication processor 1090 for performing communication functions for voice communication and data communication. A peripheral device interface 1023 may control connections between the input/output controller 1040, the communication processor 1090, the processor 1022, and a memory interface 1021. The processor 1022 controls a plurality of base stations to provide services by using at least one software program. In this case, the processor 1022 may execute at least one program stored in the memory 1010 and thus provide a service corresponding to the at least one program.

The input/output controller 1040 may provide an interface between an input/output device, such as the display unit 1050 and the input device 1060, and the peripheral device interface 1023. The display unit 1050 displays state information, input characters, moving pictures, still pictures, and the like. For example, the display unit 1050 may display information regarding application programs executed by the processor 1022.

The input device 1060 may provide input data, which is generated based on a selection by an electronic device, to the processor unit 1020 through the input/output controller 1040. In this case, the input device 1060 may include a keypad including at least one hardware button, a touch pad for detecting touch information, and the like. For example, the input device 1060 may provide the processor 1022 with touch information such as a touch, a touch motion, or a touch release sensed through the touch pad, via the input/output controller 1040.

The communication processor 1090 may include the signal transmission structures described with reference to FIGS. 1 to 13. For example, the communication processor 1090 may include a multi-layer circuit board and a waveguide, and the multi-layer circuit board may include a transition structure. The communication processor 1090 may use the transition structure to perform mode conversion of a signal transmitted through a transmission line included in the multi-layer circuit board, thereby propagating (or radiating) the signal into the waveguide. Accordingly, the communication processor 1090 may be easily manufactured and implemented with a relatively small volume and may mode-convert signals in directions both perpendicular and parallel to the propagation direction of the transmission line, allowing the signals to flow towards the waveguide.

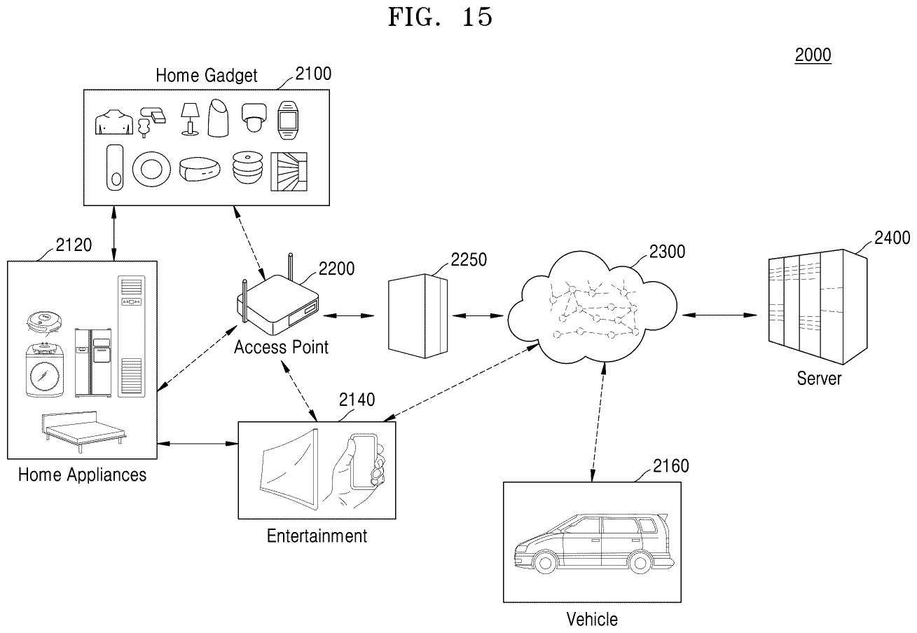

FIG. 15 is a conceptual view illustrating an Internet of Things (IoT) network system to which embodiments are applied.

Referring to FIG. 15, an IoT network system 2000 may include a plurality of IoT devices 2100, 2120, 2140, and/or 2160, an access point 2200, a gateway 2250, a wireless network 2300, and/or a server 2400. The IoT may refer to a network between devices that communicate with each other using wired/wireless communication.

Each of the IoT devices 2100, 2120, 2140, and/or 2160 may form a group depending on the characteristics of each IoT device. For example, the IoT devices may be grouped into a home gadget group 2100, a home appliance/furniture group 2120, an entertainment group 2140, and/or a vehicle group 2160. The IoT devices 2100, 2120, and 2140 may be connected to a communication network or other IoT devices through the access point 2200. The access point 2200 may be embedded in a single IoT device. The gateway 2250 may change a protocol to allow the access point 2200 to access an external wireless network. The IoT devices 2100, 2120, and 2140 may be connected to an external communication network through the gateway 2250. The wireless network 2300 may include the Internet and/or a public network. The IoT devices 2100, 2120, 2140, and/or 2160 may be connected to the server 2400 providing certain services through the wireless network 2300, and a user may access the services via at least one of the IoT devices 2100, 2120, 2140, and/or 2160.

The IoT devices 2100, 2120, 2140, and/or 2160 may include the signal transmission structures described above with reference to FIGS. 1 to 13. For example, the IoT devices 2100, 2120, 2140, and/or 2160 may include the multi-layer circuit boards and the waveguides, and the multi-layer circuit board may include the transition structure. The communication processor 1090 may use the transition structure to perform mode conversion of a signal transmitted through a transmission line included in the multi-layer circuit board, thereby propagating (or radiating) the signal into the waveguide. Accordingly, the IoT devices 2100, 2120, 2140, and/or 2160 may be easily manufactured and implemented with relatively small volumes and perform mode conversion of signals in directions both perpendicular and parallel to the propagation direction of the transmission line, thereby allowing the signals to flow into the waveguides.

Conventional structures for signal transmission involve a patch antenna on a substrate. However, the patch antenna on the substrate limits connection of a waveguide to only a direction perpendicular to a propagation direction of a transmission line. Also, conventional structures using external waveguide structures connected in a direction parallel to the propagation of the transmission line have excessively large volumes.

However, according to embodiments, improved structures are provided for signal transmission. For example, the improved structures involve radiation of signals from transmission lines in a substrate through a loop antenna transition structure. Accordingly, propagation of the radiation of the signals is not limited to a single direction. Also, the loop antenna transition structure is implemented in the substrate, and thus, has a reduced volume compared to the conventional structures.

According to embodiments, operations described herein as being performed by the electronic device 1000, the processor unit 1020, the input/output controller 1040, the communication processor 1090, the peripheral device interface 1023, the processor 1022, the memory interface 1021, the IoT network system 2000, each among the plurality of IoT devices 2100, 2120, 2140, and/or 2160, the access point 2200, the gateway 2250, and/or the server 2400 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm, and/or functions, described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Spatially relative terms, such as “beneath,” “below,” “lower,” “above,” “upper” and the like, may be used herein for ease of description to describe one element or feature's relationship to another element(s) or feature(s) as illustrated in the figures. For example, as used herein, the terms “upper,” “higher,” “on” and/or “top” may refer to an element or feature further in a given direction with respect to another element or feature, and the terms “lower” and/or “below” may refer to an element or feature further in a direction opposite the given direction with respect to another element or feature. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to another element, it may be directly connected or coupled to the other element or intervening elements may be present. As used herein the term “and/or” includes any and all combinations of one or more of the associated listed items. Other words used to describe the relationship between elements should be interpreted in a like fashion (e.g., “between” versus “directly between,” “adjacent” versus “directly adjacent,” etc.).

Embodiments are described herein with reference to cross-sectional illustrations that are schematic illustrations of idealized examples. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Although terms of “first” or “second” may be used to explain various components, the components are not limited to the terms. These terms should be used only to distinguish one component from another component. For example, a “first” component may be referred to as a “second” component, or similarly, and the “second” component may be referred to as the “first” component. Expressions such as “at least one of” when preceding a list of elements, modify the entire list of elements and do not modify the individual elements of the list. For example, the expression, “at least one of a, b, and c,” should be understood as including only a, only b, only c, both a and b, both a and c, both b and c, all of a, b, and c, or any variations of the aforementioned examples. As used herein the term “and/or” includes any and all combinations of one or more of the associated listed items.

While the inventive concepts have been particularly shown and described with reference to embodiments thereof, it will be understood that various changes in form and details may be made therein without departing from the spirit and scope of the following claims.

What is claimed is:

1. A signal transmission structure comprising:
a first multi-layer circuit board including a plurality of layers, a transition structure and a cavity structure, the plurality of layers including a ground plane and a first transmission line; and
a waveguide,
wherein
the transition structure includes,
a first metal plane included in at least one of the plurality of layers,
a first via electrically connecting the first transmission line to the first metal plane, and
a second via electrically connecting the ground plane to the first metal plane,
the transition structure is configured to mode-convert a first signal transmitted through the first transmission line into a second signal,
the cavity structure is configured such that,
a plurality of vias surrounding side surfaces of the transition structure form side surfaces of the cavity structure, and
the waveguide is on an upper surface of a topmost layer among the plurality of layers, the waveguide being connected to the cavity structure, and the waveguide being configured to propagate the second signal.

2. The signal transmission structure of claim 1, wherein
the ground plane is on a first layer among the plurality of layers;
the first transmission line is on a second layer among the plurality of layers, the second layer being closer to the topmost layer than the first layer;
the first metal plane is on the topmost layer; and
the cavity structure is configured such that,
a second metal plane included in a third layer among the plurality of layers forms a lower surface of the cavity structure,
the second metal plane is between the second layer and the topmost layer, the second metal plane being electrically connected to the ground plane through a third via, and
the second via electrically connects the second metal plane to the first metal plane.

3. The signal transmission structure of claim 1, wherein
the ground plane and the first transmission line are on a first layer among the plurality of layers;
the first metal plane is on the topmost layer; and
the cavity structure is configured such that,
a second metal plane and a third metal plane form a lower surface of the cavity structure, the third metal plane being included in a second layer among the plurality of layers, and the second metal plane being included in a third layer among the plurality of layers,
the third layer is between the second layer and the topmost layer, the third layer being closer to the topmost layer than the first layer, and the second metal plane being electrically connected to the ground plane through a third via, and
the second via electrically connects the second metal plane to the first metal plane.

4. The signal transmission structure of claim 1, wherein
the first transmission line and the first metal plane are on the topmost layer; and
the ground plane is on a first layer among the plurality of layers, the first layer being different from the topmost layer.

5. The signal transmission structure of claim 4, wherein
the transition structure includes a second metal plane on a layer between the topmost layer and the first layer among the plurality of layers;
the second via electrically connects the second metal plane to the first metal plane; and
the first via electrically connects the second metal plane, the first metal plane and the ground plane.

6. The signal transmission structure of claim 1, wherein the waveguide is configured to propagate the second signal in a direction parallel to the upper surface of the topmost layer.

7. The signal transmission structure of claim 6, wherein the first metal plane is on a layer that is different from the topmost layer among the plurality of layers.

8. The signal transmission structure of claim 7, wherein
at least one of the side surfaces of the cavity structure is in a stepped structure extended away from the transition structure, the stepped structure including the plurality of vias extending towards upper layers among the plurality of layers.

9. The signal transmission structure of claim 8, wherein
the waveguide includes an inner region; and
the inner region is filled with air and includes at least one solder ball.

10. The signal transmission structure of claim 1, further comprising:
a second multi-layer circuit board including a second transmission line,
wherein the waveguide is connected to the second transmission line through a transition structure of the second multi-layer circuit board, the transition structure of the second multi-layer circuit board having a same structure as the transition structure of the first multi-layer circuit board, and the transition structure of the second multi-layer circuit board being configured to propagate the second signal based on mode conversion of the second signal.

11. The signal transmission structure of claim 1, wherein the waveguide is configured to propagate the second signal in a direction perpendicular to the upper surface of the topmost layer.

12. The signal transmission structure of claim 11, wherein the waveguide is connected to an antenna structure and configured to propagate the second signal to the antenna structure.

13. The signal transmission structure of claim 1, wherein the first transmission line includes at least one of a microstrip, a stripline, a Co-Planar Waveguide (CPW) or a Grounded Co-Planar Waveguide (GCPW).

14. A signal transmission structure comprising:
a ground plane;
a first transmission line;
a transition structure;
a cavity structure; and
a waveguide,
wherein
the transition structure electrically connects the first transmission line to a first metal plane included in at least one of a plurality of layers of a multi-layer circuit board, the transition structure being configured to form a loop by electrically connecting the ground plane to the first metal plane, and the transition structure being configured to mode-convert a first signal transmitted through the first transmission line along the loop into a second signal,
the cavity structure is configured such that a plurality of vias surrounding side surfaces of the transition structure form side surfaces of the cavity structure, and
the waveguide is on an upper surface of a topmost layer among the plurality of layers, the waveguide being connected to the cavity structure, and the waveguide being configured to propagate the second signal.

15. The signal transmission structure of claim 14, wherein the waveguide is configured to propagate the second signal in a direction parallel to the upper surface of the topmost layer.

16. The signal transmission structure of claim 14, wherein the waveguide is configured to propagate the second signal in a direction perpendicular to the upper surface of the topmost layer.

17. An electronic device comprising:
a communication circuit including a multi-layer circuit board and a waveguide, the multi-layer circuit board including a plurality of layers, a transition structure and a cavity structure, and the plurality of layers including a ground plane and a first transmission line; and
processing circuitry configured to execute an instruction based on a signal received from the communication circuit,
wherein
the transition structure electrically connects the first transmission line to a first metal plane included in at least one of the plurality of layers, the transition structure electrically connecting the ground plane to the first metal plane, the transition structure being configured to form a loop according to a first signal transmitted through the first transmission line, and the transition structure being configured to mode-convert the first signal into a second signal along the loop,
the cavity structure is configured such that a plurality of vias surrounding side surfaces of the transition structure form side surfaces of the cavity structure, and
the waveguide is on an upper surface of a topmost layer among the plurality of layers, the waveguide being connected to the cavity structure, and the waveguide being configured to propagate the second signal.

18. The electronic device of claim 17, wherein the waveguide is configured to propagate the second signal in a direction parallel to the upper surface of the topmost layer.

19. The electronic device of claim 17, wherein the waveguide is configured to propagate the second signal in a direction perpendicular to the upper surface of the topmost layer.

20. The electronic device of claim 17, wherein the first transmission line includes at least one of a microstrip, a stripline, a Co-Planar Waveguide (CPW) or a Grounded Co-Planar Waveguide (GCPW).
